(19) United States
(12) Patent Application Publication
(10) Pub. No.: US 2010/0258171 A1
(43) Pub. Date: Oct. 14, 2010

(54) SOLAR PHOTOVOLTAIC DEVICE

(76) Inventors: Yung-Szu Su, Hsinchu (TW); Tsung-Hsien Liu, Hsinchu (TW); Wu-Tsung Lo, Hsinchu (TW); Shih-Chang Lee, Hsinchu (TW); Yu-Chih Yang, Hsinchu (TW)

Correspondence Address: Muncy, Geissler, Olds & Lowe, PLLC, 4000 Legato Road, Suite 310, FAIRFAX, VA, 22033, US

(21) Appl. No.: 12/757,507

(22) Filed: Apr. 9, 2010

(30) Foreign Application Priority Data
Apr. 9, 2009 (TW) 098111844
Apr. 20, 2009 (CN) 200910132804.6

(51) Int. Cl. H01L 31/00

(52) U.S. Cl. 136/255; 136/256

(57) ABSTRACT

A solar photovoltaic device is provided and includes a solar cell body, a window layer on the solar cell body, and a current collection layer on the window layer. The current collection layer includes a patterned structure, and a portion of the window layer is exposed by the patterned structure.

### TECHNICAL FIELD

The application relates to a solar photovoltaic device, and more particularly to a solar photovoltaic device having a solar cell body with improved photovoltaic-converting efficiency.

### REFERENCE TO RELATED APPLICATION

This application claims the right of priority based on TW application Ser. No. 098111844, filed “Apr. 9, 2009”, entitled “SOLAR PHOTOVOLTAIC DEVICE” and the contents of which are incorporated herein by reference in its entirety.

### DESCRIPTION OF BACKGROUND ART

Because of the shortage of the petroleum energy resource and the promotion of the environment protection, people continuously and actively study the art related to the replaceable energy resource and the regenerative energy resource in order to reduce the dependence of petroleum energy resource and the influence on the environment. The solar cell is an attractive candidate among those replaceable energy resources and the regenerative energy resource because the solar cell can directly convert solar energy into electricity. In addition, there are no injurious substances like carbon oxide or nitride generated during the process of generating electricity so there is no pollution to the environment.

Referring to FIG. 1 which is a schematic view of a tandem solar cell, the tandem solar cell 100 stacked by three solar cells includes a substrate 110, a bottom cell 120, a tunnel diode 130, a mediate cell 140, another tunnel diode 150, a top cell 160, a window layer 170, a cap layer 180, and a front contact 190. The top cell 160, the mediate cell 170, and the bottom cell 120 are AlGaInP cell, GaAs cell, and Ge cell respectively, and the wavelength range of the incident light absorbed by those cells are 300 nm˜660 nm, 660 nm˜900 nm, and 900 nm˜1800 nm respectively. Theoretically, the current densities generated by the top cell 160, the mediate cell 140, and the bottom cell 120 are 0.01596A/cm², 0.01587A/cm², and 0.02924 A/cm² respectively.

Accordingly, the tandem solar cell 100 can absorb wide spectrum range of the incident light which is from 300 nm to 1800 nm, wherein the wavelength of the incident light absorbed by the bottom cell 120 is the longest.

### SUMMARY OF DISCLOSURE

The present application provides a solar photovoltaic device which can improve photovoltaic-converting efficiency of the tandem solar cell.

The present application provides a solar photovoltaic device including a solar cell body, a window layer located on the solar cell body, and a current collection layer located on the window layer. The current collection layer includes a patterned structure, wherein the patterned structure exposes a portion of the window layer.

In accordance with an embodiment of the present application, the band gap (E_{g}) of the above current collection layer is larger than or equal to that of the window layer.

In accordance with an embodiment of the present application, the material of the above current collection layer includes GaP, AlN, AlInP, ITO, ZnP, IZO, AZO, GZO, or ZnO.

In accordance with an embodiment of the present application, the above current collection layer can be a transparent conductive layer and the material thereof includes ITO, ZnP, IZO, AZO, GZO, or ZnO.

In accordance with an embodiment of the present application, the reflectivity of the above current collection layer is less than 40%.

In accordance with an embodiment of the present application, the doping of the above current collection layer is n-type and the dopant thereof includes Si, Te, Sb, Ge, or other suitable dopants.

In accordance with an embodiment of the present application, the doping of the above current collection layer is p-type and the dopant thereof includes C, Mg, Zn, or other suitable dopants.

In accordance with an embodiment of the present application, the pattern of the above patterned structure is selected from a group consisting of grid, stripe, and finger.

In accordance with an embodiment of the present application, the solar photovoltaic device further includes a patterned front contact and a cap layer. The patterned front contact is located on at least a part of the current collection layer and the window layer. The cap layer is located between the current collection layer and the patterned front contact and between the window layer and the patterned front contact wherein the current collection layer is etched to form a pattern which is different from that of the patterned front contact.

In accordance with an embodiment of the present application, the solar photovoltaic device further includes an anti-reflective layer located on the surface of the current collection layer.

In accordance with an embodiment of the present application, the ratio of the openings area of the above current collection layer is between 0.3 and 0.7, better between 0.5 and 0.7.

In accordance with an embodiment of the present application, the thickness of the above current collection layer is between 200 Å and 8000 Å.

In accordance with an embodiment of the present application, the solar photovoltaic device further includes a transparent conductive layer on the current collection layer and an anti-reflective layer on the transparent conductive layer.

In accordance with an embodiment of the present application, when a transparent conductive layer is located on the current collection layer, the above a transparent conductive layer and the current collection layer include the same or different patterned structures. In addition, the above solar photovoltaic device further includes a patterned front contact located on at least a part of the current collection layer and the transparent conductive layer, and a cap layer located between the current collection layer and the patterned front contact and between the transparent conductive layer and the patterned front contact

In accordance with another embodiment of the present application, the solar photovoltaic device includes a solar cell body, a window layer located on the solar cell body, and a current collection layer located on the window layer, wherein the resistance of the current collection layer is lower than that of the window layer and the current collection layer includes a patterned structure to expose a portion of the window layer.

In accordance with another embodiment of the present application, the pattern of the above patterned structure is selected from a group consisting of grid, stripe, and finger.

In accordance with another embodiment of the present application, the ratio of the openings area of the above current collection layer is between 0.542 and 0.7.

In accordance with another embodiment of the present application, the solar photovoltaic device further includes a transparent conductive layer on the current collection layer, wherein the transparent conductive layer and the current collection layer include the same or different patterned structures.

Based on the above description, the top cell of the solar photovoltaic device is partially covered by a current collection layer so the current-collecting efficiency of the solar photovoltaic device can be improved. Because the transparent conductive layer can absorb a part of incident light having long wavelength, however, the current density generated by the bottom cell can not match with that generated by the top cell so the series current of the solar photovoltaic device is reduced. Forming openings at the current collection layer can have the current of the top cell matched with that of the bottom cell and increase current-collecting efficiency.

The foregoing aspects and many of the attendant purpose, technology, characteristic, and function, of this application will become more readily appreciated as the same becomes better understood by reference to the following embodiments detailed description, when taken in conjunction with the accompanying drawings

### BRIEF DESCRIPTION OF THE DRAWINGS

FIG. 1 illustrates a schematic view of a conventional tandem solar cell.

FIG. 2 illustrates a top plan view of a solar photovoltaic device in accordance with an embodiment of present application.

FIG. 3 illustrates a cross-sectional view of the solar photovoltaic device of FIG. 2 in view of A1-A2 line.

FIG. 4 illustrates a top plan view in accordance with a variable embodiment of the solar photovoltaic device of FIG. 2.

FIG. 5 illustrates a cross-sectional view in accordance with another variable embodiment of the solar photovoltaic device of FIG. 2.

FIG. 6 illustrates a cross-sectional view in accordance with another embodiment of present application.

FIG. 7 illustrates a cross-sectional view in accordance with another embodiment of present application.

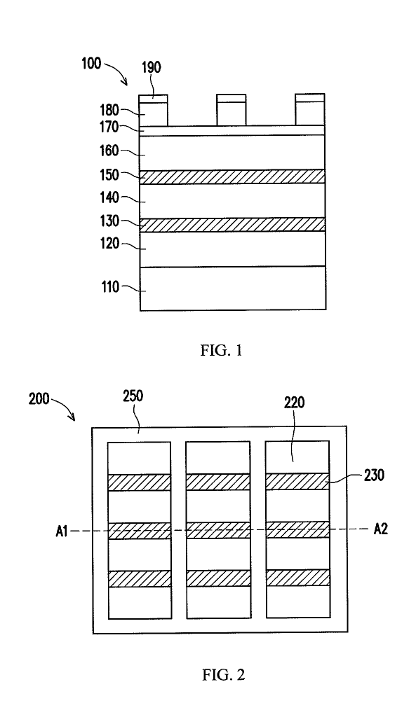

### DETAILED DESCRIPTION OF PREFERRED EMBODIMENTS

The embodiments of present application will be described in detail and sketched in figures.

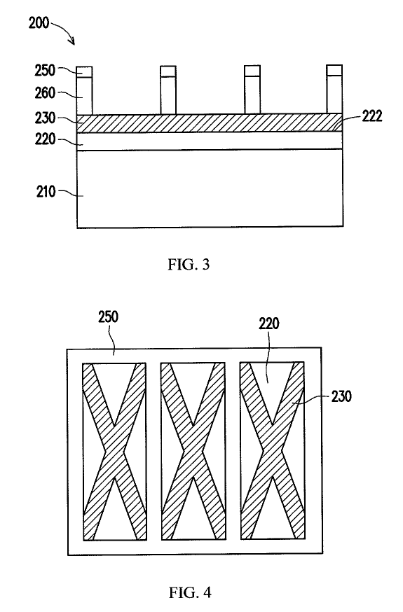

FIG. 2 illustrates a cross-sectional view of a solar photovoltaic device 200 in accordance with an embodiment of the present application. FIG. 3 illustrates a cross-sectional view of the solar photovoltaic device of FIG. 2 in view of A1-A2 line.

Referring to FIG. 2 and FIG. 3, the solar photovoltaic device 200 can be formed by stacking several solar cell bodies. The present application does not, however, limit the number of the solar cell bodies. A solar cell body 210 shown in FIG. 3 is for explanation in this embodiment, and one or more solar cell bodies are also suitable. The solar photovoltaic device 200 further includes a window layer 220 on the solar cell body 210 and a current collection layer 230 on the window layer 220. The doping concentration of the current collection layer 230 is higher than that of the window layer 220 so the resistance of the current collection layer 230 is lower than that of the window layer 220. The current collection layer 230 can increase the current-collecting efficiency of the solar cell body 210 to improve the photovoltaic-converting efficiency of the solar photovoltaic device 200.

The transmittance of the conventional current collection layer is poor in long wavelength range like larger than 1100 nm. If the top surface of the solar cell body 210 is thoroughly covered by the conventional current collection layer for increasing current-collecting efficiency, it results in that most incident light having long wavelength is absorbed by the conventional current collection layer and can not reach the bottom cell. It should be noted that the ratio of the openings area of the current collection layer 230 in this embodiment is between 0.3 and 0.7, better between 0.5 and 0.7, preferably between 0.542 and 0.7. The above ratio of the openings area is the ratio of the area of the light-facing surface 222 of the window layer 220 not covered by the current collection layer 230 and the patterned front contact 250 (it can be grid or other pattern as the drawing shows) to the total area of the light-facing surface 222. The term of “between” mentioned above includes the meaning of “equal”. When the solar photovoltaic device 200 is a tandem solar cell, the current collection layer 230 of which the ratio of the openings area is between 0.3 and 0.7 can allow the incident light having long wavelength to enter into the bottom cell (not shown) of the solar photovoltaic device 200 so the bottom cell can generate the current density matching with that of the top cell.

The band gap of the current collection layer 230 is larger than or equal to that of the window layer 220 in this embodiment. The material of the window layer 220 can be the semiconductor material like GaP, AlN, or AlInP, or the transparent conductive material like ITO, ZnP, IZO, AZO, GZO, or ZnO. In addition, the current collection layer 230 having high transmittance, of which reflectivity is less than 40% for example, can enable the incident light to penetrate the current collection layer 230 easily and to be absorbed by the solar cell body 210. The material of the current collection layer 230 can include GaP, AlN, AlInP, ITO, ZnP, IZO, AZO, GZO, or ZnO. The current collection layer 230 can be deposited on the window layer 220 by Metal Organic Chemical Vapor Deposition (MOCVD) and be etched to form the openings. In general, the thicker the thickness of the current collection layer 230 is, the better the conductivity thereof is. The transmittance of the current collection layer 230, however, can be reduced. Considering the conductivity and transmittance, the thickness of the current collection layer 230 can be between 200 Å and 8000 Å. On the other hand, if the doping of the current collection layer 230 is n-type, the dopant thereof can be Si, Te, Sb, or Ge. If the doping of the current collection layer 230 is p-type, the dopant thereof can be C, Mg, or Zn.

Referring to FIG. 2 and FIG. 3, the solar photovoltaic device 200 can include a cap layer 260. The patterned front contact 250 is located on the current collection layer 230 and a portion of the window layer 220, and the cap layer 260 is located between the current collection layer 230 and the patterned front contact 250 and between the window layer 220 and the patterned front contact 250.

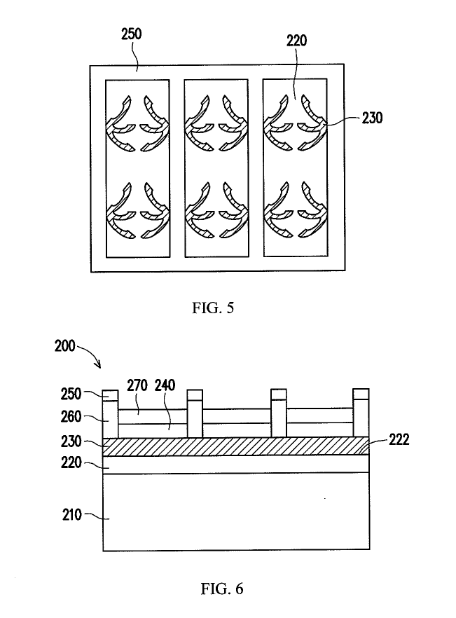

Furthermore, the pattern of the patterned structure of the current collection layer 230 can be different from that of the patterned front contact 250 and the pattern thereof is selected from a group consisting of grid, stripe, and finger. As FIG. 2 shows, the pattern of the current collection layer 230 is grid that can increase the collection of the lateral current of the solar cell body 210 as FIG. 3 shows. Because the patterned front contact 250 is usually metal, the incident light can be blocked by the patterned front contact 250. The current collection layer 230 can increase the current-collecting efficiency of the patterned front contact 250 and reduce utilization of the patterned front contact 250. Thus, it can reduce the shaded area of the solar cell body 210 where is covered by the patterned front contact 250 and increase the photovoltaic-converting efficiency thereof. Referring to FIG. 4 and FIG. 5, the main function of the current collection layer 230 having other patterns like stripe or finger is to increase the collection of the lateral current of the patterned front contact 250 in order to improve the photovoltaic-converting efficiency of the solar cell body 210, as FIG. 3 shows.

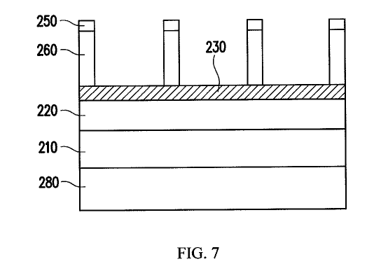

FIG. 6 is a cross-sectional view in accordance with another embodiment of present application, wherein the same symbols of FIG. 3 are employed in explaining this embodiment. Referring to FIG. 6, the difference between this embodiment and the above embodiment is that the solar photovoltaic device 200 further includes a transparent conductive layer 240 and an anti-reflective layer 270. The transmittance of the conventional transparent conductive layer is poor in long wavelength range like larger than 1100 nm. If the conventional transparent conductive layer covers thoroughly the window layer, most incident light having long wavelength can be absorbed by the conventional transparent conductive layer and can not reach the bottom cell. The ratio of the openings area of the transparent conductive layer 240 is between 0.3 and 0.7, better between 0.5 and 0.7, preferably between 0.542 and 0.7. The transparent conductive layer 240 and the current collection layer 230 can have the same or different patterned structures. The transparent conductive layer 240 can partially cover the current collection layer 230 or the window layer 220 to increase the current-collecting efficiency of solar cell body 210. The incident light having long wavelength can penetrate the openings of the transparent conductive layer 240 and reach the current collection layer 230 or the window layer 220. In this embodiment, the material of the transparent conductive layer 240 can be transparent conductive material like ITO, ZnP, IZO, AZO, GZO, or ZnO. The anti-reflective layer 270 is formed on the surfaces of the current collection layer 230, the transparent conductive layer 240 or the light-facing surface 222 to reduce the reflection of the incident light.

FIG. 7 is a cross-sectional view in accordance with another embodiment of present application, wherein the same symbols of FIG. 3 are employed in explaining this embodiment. Referring to FIG. 7, the current collection layer 230 is between the window layer 220 and the cap layer 260 in this embodiment. In addition, a back surface field (BSF) structure layer 280 can be formed on the opposite surface (not light-facing surface) of the solar cell body 210 selectively for improving the carrier-collected efficiency.

The solar photovoltaic device is not limited in the above drawings. For instance, the embodiments shown in FIG. 3 and FIG. 6 can also have the above BSF structure layer.

In summary, because the doping concentration of the current collection layer 230 is higher than that of the window layer 220 and the ratio of the openings area of the current collection layer 230 is between 0.3 and 0.7, the current collection layer 230 partially covering the light-facing surface 222 of the window layer 220 can increase the current-collecting efficiency of the solar photovoltaic device 200 and reduce the use of the patterned front contact 250. Thus, the shaded area of the patterned front contact 250 can be reduced. Moreover, the incident light having long wavelength can penetrate the openings of the current collection layer 230 and reach the bottom cell to increase the current density of the bottom cell so the photovoltaic-converting efficiency can be increased.

Although the present application has been explained above, it is not the limitation of the range, the sequence in practice, the material in practice, or the method in practice. Any modification or decoration for present application is not detached from the spirit and the range of such.

What is claimed is:

1. A solar photovoltaic device, comprising:
a solar cell body;
a window layer located on the solar cell body; and
a current collection layer located on the window layer, including a patterned structure, wherein the patterned structure exposes a portion of the window layer.

2. The solar photovoltaic device of claim 1, wherein the band gap of the current collection layer is larger than or equal to that of the window layer.

3. The solar photovoltaic device of claim 1, wherein the material of the current collection layer comprises GaP, AlN, AlInP, ITO, ZnP, IZO, AZO, GZO, or ZnO.

4. The solar photovoltaic device of claim 1, wherein the current collection layer comprises a transparent conductive layer.

5. The solar photovoltaic device of claim 4, wherein the material of the transparent conductive layer comprises ITO, ZnP, IZO, AZO, GZO, or ZnO.

6. The solar photovoltaic device of claim 1, wherein the reflectivity of the current collection layer is less than 40%.

7. The solar photovoltaic device of claim 1, wherein the doping of the current collection layer is n-type and the dopant of the current collection layer comprises Si, Te, Sb, or Ge.

8. The solar photovoltaic device of claim 1, wherein the doping of the current collection layer is p-type and the dopant of the current collection layer comprises C, Mg, or Zn.

9. The solar photovoltaic device of claim 1, wherein the pattern of the patterned structure is selected from a group consisting of grid, stripe, and finger.

10. The solar photovoltaic device of claim 1, further comprising:
a patterned front contact located on parts of the current collection layer and the window layer; and
a cap layer located between the current collection layer and the patterned front contact and between the window layer and the patterned front contact.

11. The solar photovoltaic device of claim 10, wherein the current collection layer is etched to form a pattern different from that of the patterned front contact.

12. The solar photovoltaic device of claim 1 further comprising an anti-reflective layer located on the surface of the current collection layer.

13. The solar photovoltaic device of claim 1, wherein the ratio of the openings area of the current collection layer is between 0.3 and 0.7.

14. The solar photovoltaic device of claim 1, wherein the thickness of the current collection layer is between 200 Å and 8000 Å.

15. The solar photovoltaic device of claim 1 further comprising a transparent conductive layer located on the current collection layer.

16. The solar photovoltaic device of claim 15 further comprising an anti-reflective layer located on the transparent conductive layer.

17. The solar photovoltaic device of claim 15, wherein the transparent conductive layer and the current collection layer comprise the same or different patterned structures.

18. The solar photovoltaic device of claim 17, wherein the ratio of the openings area of the patterned structures is between 0.3 and 0.7.

19. The solar photovoltaic device of claim 15, further comprising:
a patterned front contact located on parts of the current collection layer and the transparent conductive layer; and
a cap layer located between the current collection layer and the patterned front contact and between the window layer and the patterned front contact.

20. The solar photovoltaic device of claim 1, wherein the resistance of the current collection layer is lower than that of the window layer.
